(19) United States
(12) Patent Application Publication
(10) Pub. No.: US 2005/0105274 A1
(43) Pub. Date: May 19, 2005

(54) Method for reducing the thermal resistance of a heat dissipating base and a heat dissipating base using the same

(75) Inventor: Jung-Hsiang Cheng, Taipei (TW)

Correspondence Address: BRUCE H. TROXELL, SUITE 1404, 5205 LEESBURG PIKE, FALLS CHURCH, VA, 22041, US

(73) Assignee: Shuttle Inc.

(21) Appl. No.: 10/833,098

(22) Filed: Apr. 28, 2004

(30) Foreign Application Priority Data
Nov. 19, 2003 (TW) 092132435

(51) Int. Cl. H05K 7/20

(52) U.S. Cl. 361/700; 361/697

(57) ABSTRACT

The present invention provides a method for reducing the thermal resistance of a heat dissipating base, which comprises the steps of: providing a base, having at least one guide slot that is not penetrating inside said base; coupling at least one heat conduction pipe to an outlet of said guide slot; sintering some copper powder on a inner wall of said guide slot and said heat conduction pipe respectively for conducting heat; injecting some liquid into said heat conduction pipe for heat exchanging; extracting the air of said guide slot and said heat conduction pipe to make them to become a vacuum status; and sealing another outlet of said heat conduction pipe. Furthermore, the present invention also provides a heat dissipating base.

### FIELD OF THE INVENTION

This application is the continuing application of the pending Taiwan patent application, Serial No. 091206737, filed May 13, 2002, all of which is hereby incorporated by reference.

The present invention relates generally to a CPU heat dissipating apparatus, more particularly, to a heat dissipating base that has at least one guide slot that is not penetrating inside said base, and an outlet of said guide slot is coupled to a external heat conduction pipe so as to reduce the thermal resistance of the heat dissipating base.

### BACKGROUND OF THE INVENTION

Please refer to FIG. 1, which shows a diagram of a prior art CPU heat dissipating apparatus with thermal pipe. As shown in FIG. 1, the prior art CPU heat dissipating apparatus with thermal pipe includes: at least one thermal pipe 51, having a metal weaving net inside the thermal pipe (not shown) for conducting heat; fin 52, the button of the fin 52 is hollow and at least one thermal pipe 53 is pierced through and bound to the button of the fin 52 by viscose (such as Tin paste) and then a metal sheet 54 is covered over the button of the fin 52; a fastener 55, for fastening the fin 52 to a slot (not shown); a plurality of heat sink (not shown), wherein every heat sink has a plurality of holes and the number of which is relative to the number of the thermal pipe 51 and every heat sink overlaps each other so as to pierce at least one thermal pipe 51 through the a plurality of heat sink; and a covering fan 56. However the prior art CPU heat dissipating apparatus has the following drawbacks: 1) due to the at least one thermal pipe 53 is pierced through and bound to the button of the fin 52 by viscose and then a metal sheet 54 is covered over the button of the fin 52, therefore, a thermal resistance is easy generated between the viscose and the fin 52, thus will reduce the heat dissipating efficiency of the fin 52; 2) The at least one thermal pipe 53 is pierced through the button of the fin 52, therefore the thermal pipe 53 must has two seals, but the seals also increases the thermal resistance; 3) The operator must prior pierces at least one thermal pipe 53 through and binds to the button of the fin 52 by the viscose and then covers the metal sheet 54 over the button of the fin 52 while the heat dissipating apparatus is assembled, thus will take more time.

Therefore, it needs a heat dissipating base and a method for reducing the thermal resistance of the heat dissipating base, wherein the heat dissipating base has at least one guide slot that is not penetrating inside said base, and an outlet of said guide slot is coupled to a external heat conduction pipe so as to reduce the thermal resistance of the heat dissipating base and save the assembly time.

### SUMMARY OF THE INVENTION

To solve the above problems, it is an object of the present invention to provide a method for reducing the thermal resistance of the heat dissipating base to reduce the thermal resistance of the heat dissipating base and save the assembly time.

To accomplish the above object of the present invention, the method for measuring the temperature of a computer system comprising the following steps: providing a base, having at least one guide slot that is not penetrating inside said base; coupling at least one heat conduction pipe to an outlet of said guide slot; sintering some copper powder on a inner wall of said guide slot and said heat conduction pipe respectively for conducting heat; injecting some liquid into said heat conduction pipe for heat exchanging; extracting the air of said guide slot and said heat conduction pipe to make them to become a vacuum; and sealing another outlet of said heat conduction pipe.

To solve the above problems, it is another object of the present invention to provide a heat dissipating base that has at least one guide slot that is not penetrating inside said base, and an outlet of said guide slot is coupled to a external heat conduction pipe so as to reduce the thermal resistance of the heat dissipating base and save the assembly time.

To accomplish the above object of the present invention, the heat dissipating base comprises: a base, having at least one guide slot that is not penetrating inside said base, and some copper powder sintered on a inner wall of said guide slot for conducting heat; at least one heat conduction pipe, one end of said heat conduction pipe coupled to an outlet of said guide slot, and also some copper powder sintered on a inner wall of said heat conduction pipe for conducting heat, the other end of said heat conduction pipe having a seal; and some liquid, positioned inside said guide slot and said heat conduction pipe, thereby, the heat dissipating base can execute heat dissipating by the heat exchanging of said liquid and said copper powder.

The novel features of the invention are set forth with particularity in the appended claims. The invention will be best understood from the following description when read in conjunction with the accompanying drawings.

### BRIEF DESCRIPTION OF THE DRAWINGS

FIG. 1 shows a diagram of a prior art CPU heat dissipating apparatus with thermal pipe.

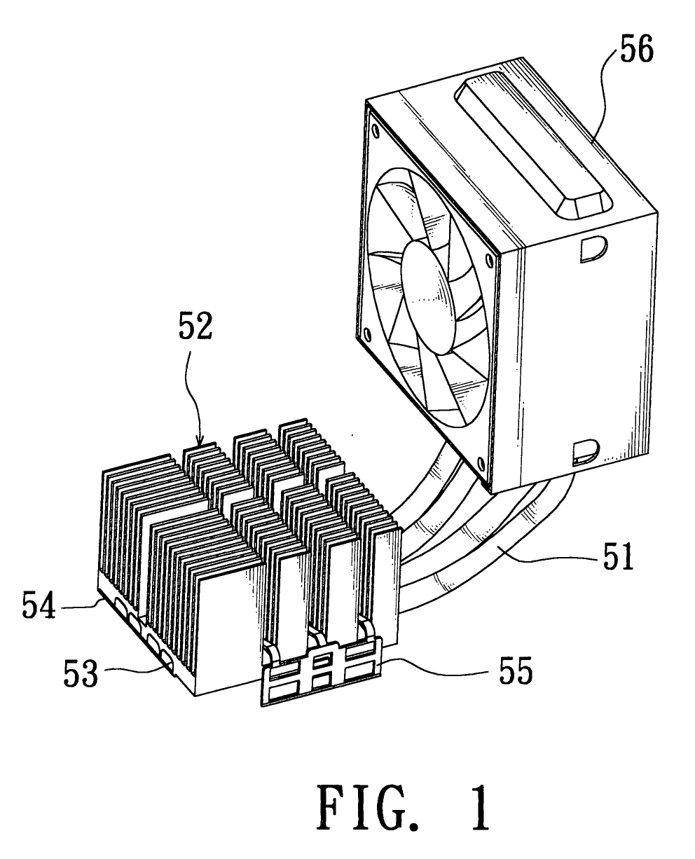

FIG. 2 shows a diagram of a heat dissipating base in accordance with one embodiment of the present invention.

FIG. 3 shows a sectional drawing view of a guide slot and a thermal pipe in accordance with one embodiment of the present invention.

### DESCRIPTION OF THE PREFERRED EMBODIMENTS

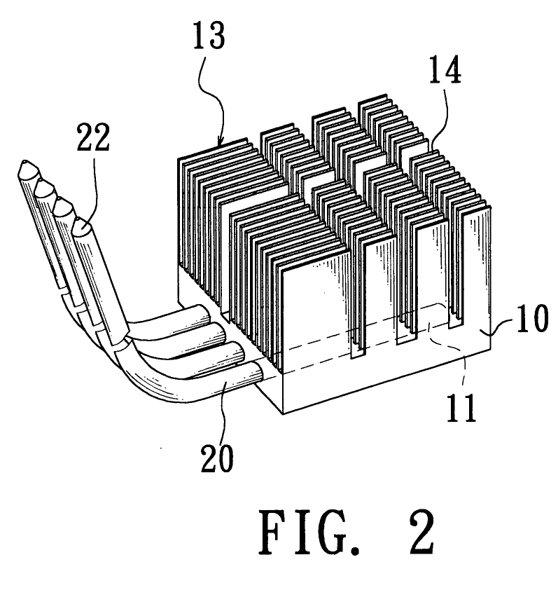

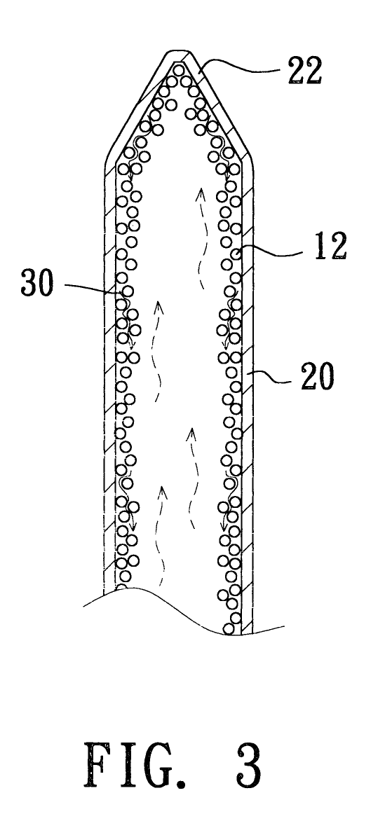

Referring to FIG. 2 shows a diagram of a heat dissipating base in accordance with one embodiment of the present invention. As shown in FIG. 2, the heat dissipating base with lower thermal resistance, which comprises: a base 10; at least one heat conduction pipe 20 and some liquid 30.

Wherein, using the molding method to make the base 10 is preferred. The base 10 made by the molding method in addition to save the assembly time, also overcomes the drawback that thermal resistance is increasing due to fill some Tin paste between the guide slot 11 and heat conduction pipe 20. Besides, at least one guide slot 11 that is not penetrating inside said base 10 for purpose to reduce a seal of the guide slot 11, and some copper powder 12 (please refer to FIG. 3) is sintered on a inner wall of said guide slot 11 so that the liquid for example but not limited to water passing the inner wall of said guide slot 11 can form a capillarity effect for conducting heat. Wherein, the base 10 is preferably made of metal material for example but not limited to copper to increase the heat dissipating efficiency. The shape of the guide slot 11 is for example but not limited to a circular slot; besides, the shape of the base can be square, rectangle, diamond, circular, oval, or other shapes, wherein the square shape (as shown in FIG. 2) is preferred.

The at least one heat conduction pipe 20, one end is coupled to the outlet of the guide slot 11 and some copper powder 12 is sintered on the inner wall of the heat conduction pipe 20 for conducting heat; another end of the heat conduction pipe 20 has a seal 22 and the number of the seal 22 equals to the number of the guide slot 11. The liquid 30 is positioned inside the guide slot 11 and heat conduction pipe 20 to exhaust out the heat by the liquid 30 flowing inside the guide slot 11 and the heat conduction pipe 20 and completes the heat exchanging by the copper powder 12. Furthermore, some fins 14 can be installed on the top 13 of the base 10 to improve the heat dissipating efficiency.

Referring to FIG. 3 shows a sectional drawing view of a guide slot 11 and a heat conduction pipe 20 in accordance with one embodiment of the present invention. As shown in FIG. 3, the base 10 of the present invention can be sintered copper powder 12 on the inner wall of the guide slot 11 and heat conduction pipe 20 so as to make the copper powder 12 be attached to the inner wall. The sintering temperature of the present invention is for example but not limited to 1000° C., thereby, while the liquid 30 passing through the inner wall of the guide slot 11 and heat conduction pipe 20, the contacting time between the liquid 30 and the copper powder 12 can be increased so as to execute the heat exchanging, and then to execute the heat dissipating.

The working situation of the present invention is: due to the inner wall of the guide slot 11 and heat conduction pipe 20 having copper powder 12 sintered and some liquid 30, while heat generated by the CPU is conducted to the guide slot 11 by the fin 14, using the theorem that the water will be evaporated and become vapor when the water meets heat, and the heat vapor will rise to the upper place of the guide slot 11 and heat conduction pipe 20, thus, the hot air will be conducted to the seal 22. Further, an external heat sink (not shown) can be coupled to the seal 22 for conducting the heat, and then using a fan (not shown) pumps the hot air outwardly, thus, the hot air and the cool air executes the heat exchange at the heat sink. Due to the inner wall of the guide slot 11 and heat conduction pipe 20 having copper powder 12 sintered, so the air exchanging speed can be improved, thus, the vapor in the heat conduction pipe 20 can quickly be condensed into water and flow back to lower place of the guide slot 11 and executed heat exchanging with the heat generated by the CPU again. Therefore, the heat generated by the CPU can be exhausted out of the housing (not shown) of the computer system.

Wherein, the number of the guide slot 11 and heat conduction pipe 20 is determined according to the heat generated by the CPU. Generally speaking, every guide slot 11 and heat conduction pipe 20 of the present invention can absorb about 40 W heat. Considering the heat conduction pipe 20 will be slightly bent so as to lockup the heat conduction pipe 20 to the outlet of the guide slot 11 and fasten it on the housing while the heat dissipating base is assembled, therefore, the efficiency of the heat conduction pipe 20 will be slightly reduced to about 30 W.

Furthermore, the present invention also provides a method for reducing the thermal resistance of a heat dissipating base, which comprising the following steps:
providing a base 10, having at least one guide slot 11 that is not penetrating inside said base 10 (step 1); coupling at least one heat conduction pipe 20 to an outlet of said guide slot 11 and sintering some copper powder 12 on a inner wall of said guide slot 11 and said heat conduction pipe 20 respectively for conducting heat (step 2); injecting some liquid 30 into said heat conduction pipe 20 for heat exchanging (step 3); extracting the air of said guide slot 11 and said heat conduction pipe 20 to make them to become a vacuum (step 4); and sealing another outlet of said heat conduction pipe 20 (step 5).

Wherein, the base 10 of the step 1 is made by the molding method preferably. The base 10 made by the molding method in addition to save the assembly time, also overcomes the drawback that thermal resistance is increases due to fill some Tin paste between the guide slot 11 and heat conduction pipe 20. Besides, at least one guide slot 11 that is not penetrating inside said base 10 for purpose to reduce a seal of the guide slot 11 so as to reduce the thermal resistance of the base 10. Furthermore, the shape of the base 10 can be square, rectangle, diamond, circular, oval, or other shapes, wherein the square shape (as shown in FIG. 2) is preferably.

The guide slot 11 of the step 2 has some copper powder 12 sintered on the inner wall of the guide slot 11 for conducting heat so that the liquid for example but not limited to water passing the inner wall of said guide slot 11 can form a capillarity effect for conducting heat. Wherein, the base 10 is preferably made of metal material for example but not limited to copper to increase the heat dissipating efficiency and the shape of the guide slot 11 preferably is circular shape.

The liquid 30 of step 3 injected inside the guide slot 11 and heat conduction pipe 20 is for example but not limited to water, so that the liquid 30 passing the inner wall of said guide slot 11 can form a capillarity effect for conducting heat.

The differences between the heat dissipating base of the present invention and the heat dissipating base of prior art is: the heat dissipating base of the present invention has a molded base, thus, in addition to saving the assembly time, also the thermal resistance increased due to fill some Tin paste between the guide slot 11 and heat conduction pipe 20 of the prior art can be reduced. Besides, at least one guide slot 11 that is not penetrating inside said base 10 for purpose to reduce a seal of the guide slot 11 to reduce the thermal of the base 10, thereby, reducing the thermal resistance of the base 10 to improve the heat dissipating efficiency.

While the invention has been described with reference to a preferred embodiment thereof, it is to be understood that modifications or variations may be easily made without departing from the spirit of this invention, which is defined by the appended claims.

1. A heat dissipating base with low thermal resistance, using in a heat dissipating apparatus of a computer system, which comprises:
a base, having at least one guide slot that is not penetrating inside said base, and some copper powder sintered on a inner wall of said guide slot for conducting heat;
at least one heat conduction pipe, one end of said heat conduction pipe coupled to an outlet of said guide slot, and also some copper powder sintered on a inner wall of said heat conduction pipe for conducting heat, the other end of said heat conduction pipe having a seal; and
some liquid, positioned inside said guide slot and said heat conduction pipe, thereby, the heat dissipating base can execute heat dissipating by the heat exchanging of said liquid and said copper powder.

2. A heat dissipating base as claimed in claim 1, wherein said heat dissipating base is made by molding, and is made of metal material preferably.

3. A heat dissipating base as claimed in claim 2, wherein said metal material is preferably copper.

4. A heat dissipating base as claimed in claim 1, wherein said guide slot is a round shape guide slot.

5. A heat dissipating base as claimed in claim 1, wherein the number of said guide slot and said heat conduction pipe are equal.

6. A heat dissipating base as claimed in claim 1, wherein a plurality of fins further can be installed above said heat dissipating base to improve the heat dissipating efficiency.

7. A heat dissipating base as claimed in claim 1, wherein inside said guide slot and said heat conduction pipe form a vacuum.

8. A method for reducing the thermal resistance of a heat dissipating base, using in a heat dissipating apparatus of a computer system, which comprises the following steps:
providing a base, having at least one guide slot that is not penetrating inside said base;
coupling at least one heat conduction pipe to an outlet of said guide slot;
sintering some copper powder on a inner wall of said guide slot and said heat conduction pipe respectively for conducting heat;
injecting some liquid into said heat conduction pipe for heat exchanging;
extracting the air of said guide slot and said heat conduction pipe to make them to become a vacuum; and
sealing another outlet of said heat conduction pipe.

9. A method for reducing the thermal resistance of a heat dissipating base as claimed in claim 8, wherein said heat dissipating base is made by molding, and is preferably made of metal material.

10. A method for reducing the thermal resistance of a heat dissipating base as claimed in claim 9, wherein said metal material preferably is copper.

11. A method for reducing the thermal resistance of a heat dissipating base as claimed in claim 8, wherein said guide slot is a round shape guide slot.

12. A method for reducing the thermal resistance of a heat dissipating base as claimed in claim 8, wherein the number of said guide slot and said heat conduction pipe are equal.

13. A method for reducing the thermal resistance of a heat dissipating base as claimed in claim 8, wherein a plurality of fins further can be installed above said heat dissipating base to improve the heat dissipating efficiency.
